(19) United States
(12) Patent Application Publication
(10) Pub. No.: US 2008/0081475 A1
(43) Pub. Date: Apr. 3, 2008

(54) Method for forming pattern in semiconductor device

(75) Inventors: Ki-Won Nam, Kyoungki-do (KR); Jae-Young Kim, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/716,843

(22) Filed: Mar. 12, 2007

(30) Foreign Application Priority Data
Sep. 29, 2006 (KR) 2006-0096443

(51) Int. Cl. H01L 21/461

(52) U.S. Cl. 438/690; 438/689; 438/734; 257/E21.002

(57) ABSTRACT

A method for forming a pattern in a semiconductor device includes forming an etch target layer and a hard mask layer, forming a mask pattern over the hard mask layer, etching the hard mask layer using the mask pattern as an etch mask, removing polymers generated while etching the hard mask layer, and etching the etch target layer to form a pattern using the mask pattern as an etch mask.

### CROSS-REFERENCE TO RELATED APPLICATIONS

The present invention claims priority of Korean patent application number 10-2006-0096443, filed on Sep. 29, 2006, which is incorporated by reference in its entirety.

### BACKGROUND OF THE INVENTION

The present invention relates to a method for fabricating a semiconductor device, and more particularly, to a method for forming a bit line pattern in a semiconductor device.

During a typical process for forming a bit line pattern in a semiconductor device, a bit line hard mask is formed and a bottom metal electrode and a polysilicon layer are then etched using the bit line hard mask as an etch mask. However, a top portion of the bit line pattern is often damaged when lower layers are etched using the bit line hard mask as an etch mask. Thus, a mask pattern formed to pattern the bit line hard mask is not removed and used as the etch mask for etching the lower layers in order to reduce the damage of the top portion.

FIGS. 1A and 1B illustrate cross-sectional views showing a typical method for forming a pattern in a semiconductor device. Referring to FIG. 1A, an insulation layer 12 is formed over a substrate 11. A barrier metal layer 13 and a metal electrode layer 14 are formed over the insulation layer 12. A hard mask layer is formed over the metal electrode layer 14. The hard mask layer is patterned to form bit line hard masks 15. The bit line hard masks 15 may be formed by forming a mask pattern 16 over the hard mask layer and patterning the hard mask layer using the mask pattern 16. The mask pattern 16 may include a stack structure configured with amorphous carbon, an anti-reflective coating layer (silicon oxynitride (SiON)), and a photoresist pattern. While patterning the bit line hard masks 15, polymers 17 may be formed over sidewalls of the bit line hard masks 15. Referring to FIG. 1B, the metal electrode layer 14 and the barrier metal layer 13 are etched to form bit line patterns using the mask pattern 16 as an etch mask. Thus, the bit line patterns, each including a stack structure configured with a barrier metal 13A and a metal electrode 14A, are formed.

According to the typical method, the mask pattern 16 remains after forming the bit line hard masks 15 and is used for patterning the metal electrode layer 14 and the barrier metal layer 13 in order to reduce damage of top portions of the bit line patterns. However, a positive profile may be formed due to the polymers 17 formed over the sidewalls of the bit line hard masks 15 during the patterning of the bit line hard masks 15. Consequently, the polymers 17 function as an etch mask when lower layers are etched, and thus, a final width W₁₂ of the bit line patterns becomes larger than a width W₁₁ of the bit line hard masks 15. As the final width W₁₂ of the bit line patterns increases, a margin decreases when forming a subsequent storage node contact hole. Thus, a limitation may occur when forming a self-aligned contact (SAC).

### SUMMARY OF THE INVENTION

Embodiments of the present invention are directed to provide a method for forming a pattern in a semiconductor device, which can reduce difficulties occurring when forming a self-aligned contact (SAC), wherein polymers generated while patterning a bit line hard mask increases a width of a bit line pattern and causes a margin to decrease during a subsequent storage node contact hole formation to generate the difficulties.

In accordance with an aspect of the present invention, there is provided a method for forming a pattern in a semiconductor device, including: forming an etch target layer and a hard mask layer; forming a mask pattern over the hard mask layer; etching the hard mask layer using the mask pattern as an etch mask; removing polymers generated while etching the hard mask layer; and etching the etch target layer to form a pattern using the mask pattern as an etch mask.

### BRIEF DESCRIPTION OF THE DRAWINGS

FIGS. 1A and 1B illustrate cross-sectional views showing a typical method for forming a pattern in a semiconductor device.

FIGS. 2A to 2D illustrate cross-sectional views showing a method for forming a pattern in a semiconductor device in accordance with an embodiment of the present invention.

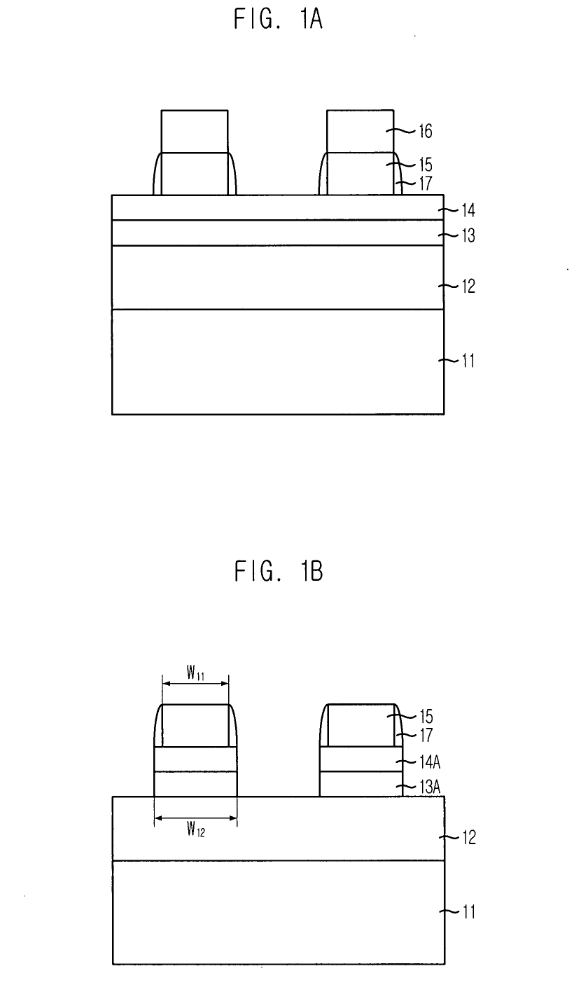

### DESCRIPTION OF SPECIFIC EMBODIMENTS

The present invention relates to a method for forming a pattern in a semiconductor device. According to an embodiment of the present invention, polymers formed over sidewalls of a bit line hard mask prior to etching a metal layer are removed and a subsequent metal electrode is additionally etched. Thus, a positive profile of the metal layer caused by the polymers may be reduced. Accordingly, bit line patterns may be patterned with a vertical profile, and thus, a self-aligned contact (SAC) margin may be increased when etching a storage node contact hole.

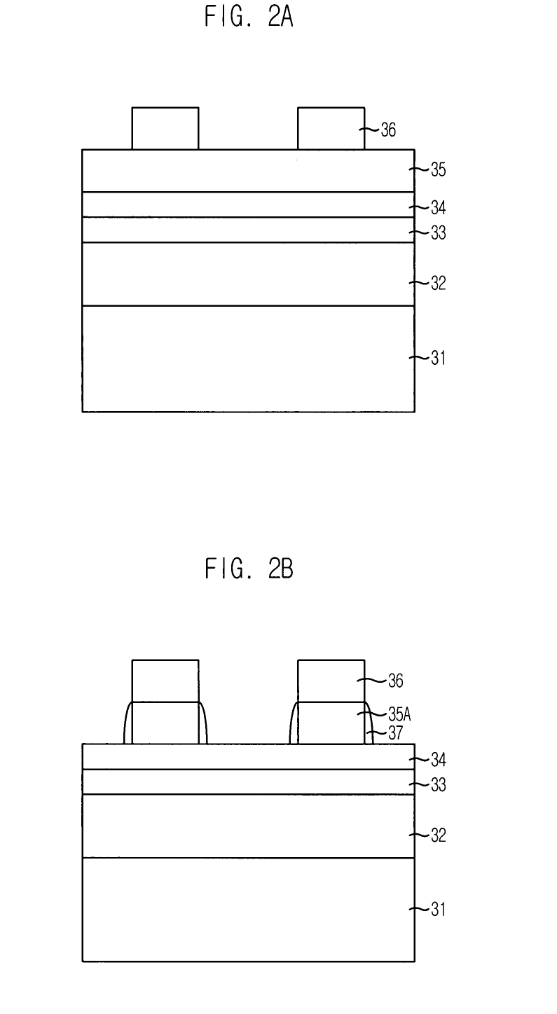

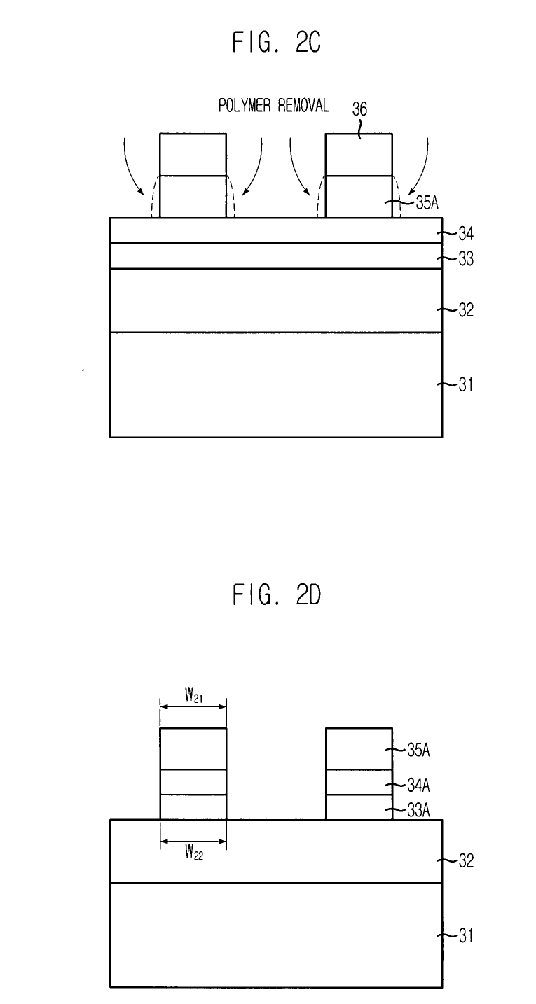

FIGS. 2A to 2D illustrate cross-sectional views showing a method for forming a pattern in a semiconductor device in accordance with an embodiment of the present invention.

Referring to FIG. 2A, an insulation layer 32 is formed over a substrate 31. The insulation layer 32 may include an oxide-based material in a single layer or a multiple-layer structure. Although not shown, gate patterns and landing plug contacts may be formed prior to forming the insulation layer 32. A barrier metal layer 33, a metal electrode layer 34, and a bit line hard mask layer 35 are formed over the insulation layer 32. The metal electrode layer 34 may include tungsten (W), the barrier metal layer 33 may include titanium (Ti)/titanium nitride (TiN), and the bit line hard mask layer 35 may includes a nitride-based material.

A mask pattern 36 is formed over the bit line hard mask layer 35. The mask pattern 36 is formed to define a bit line pattern region. The mask pattern 36 is formed by forming an amorphous carbon layer and an anti-reflective coating layer (e.g., silicon oxynitride (SiON)), and then, etching the anti-reflective coating layer and the amorphous carbon layer using a photoresist pattern. Thus, the mask pattern 36 includes a stack structure configured with the amorphous carbon layer and the anti-reflective coating layer.

Referring to FIG. 2B, the bit line hard mask layer 35 is etched to form bit line hard mask patterns 35A using the mask pattern 36 as an etch mask. At this time, polymers 37 generated while patterning the bit line hard mask patterns 35A are formed over sidewalls of the bit line hard mask patterns 35A, forming a positive profile. Thus, a width of subsequent bit line patterns may be increased by as much as a width of the polymers 37 when a subsequent etching process is continuously performed.

Referring to FIG. 2C, the polymers 37 formed over the sidewalls of the bit line hard mask patterns 35A are removed. At this time, an isotropic etching process is performed to remove the polymers 37. The isotropic etching process includes performing a dry etching process using a gas that has selectivity among the polymers 37, the bit line hard mask patterns 35A, and the mask pattern 36.

For instance, the isotropic etching process for selectively removing the polymers 37 is performed using an apparatus (e.g., an induced coupled plasma (ICP)) in which a top power and a bottom power may be supplied. The isotropic etching process may be performed supplying only the top power, or supplying both the top and bottom powers at substantially the same time, the bottom power being low. For example, the isotropic etching process is performed using a top power ranging from approximately 100 W to approximately 2,000 W, and a bottom power may not be supplied or a low bottom power ranging from approximately 1 W to approximately 5 W may be supplied. A physical impact may be increased if a high bottom power is supplied. Thus, an impact may be given to a top portion of the mask pattern 36 instead of the sidewalls of the bit line hard mask patterns 35A on which the polymers 37 are formed. Accordingly, the top portion of the bit line hard mask patterns 35A may be damaged as the subsequent etching process is performed.

Therefore, the low bottom power is supplied in this embodiment such that etch ions dissociated by the top power may remove the polymers 37 formed over the sidewalls of the bit line hard mask patterns 35A with a chemical impact instead of the physical impact. The isotropic etching process uses a gas that can remove the polymers 37.

Also, the isotropic etching process uses a gas which can selectively remove the polymers 37 without generating a loss of the bit line hard mask patterns 35A and the mask pattern 36. For instance, oxygen gas is used at a flow rate ranging from approximately 1 sccm to approximately 30 sccm. As the polymers 37 formed over the sidewalls of the bit line hard mask patterns 35A are removed, the positive profile formed by the polymers 37 is transformed into a vertical profile. Thus, the bit line patterns may be patterned with substantially the same width as the bit line hard mask patterns 35A during the subsequent etching process. Furthermore, the loss of the mask pattern 36 and the bit line hard mask patterns 35A may be reduced because the polymers 37 are selectively removed. Meanwhile, other polymers (not shown) generated while forming the mask pattern 36 may also be removed when removing the polymers 37.

Referring to FIG. 2D, the metal electrode layer 34 and the barrier metal layer 33 are etched using the remaining mask pattern 36 as an etch mask to form the bit line patterns. Each bit line pattern includes a stack structure configured with a barrier metal 33A, a metal electrode 34A, and the bit line hard mask pattern 35A. Since the polymers 37 are removed as shown in FIG. 2C, the bit line patterns may be formed with the vertical profile. Thus, a width W₂₁ of the bit line hard mask patterns 35A and a width W₂₂ of the barrier metal 33A may be substantially the same. Also, a damage may not occur on a top portion of the bit line hard mask patterns 35A because the mask pattern 36 is used until the barrier metal layer 33 is etched. Meanwhile, the mask pattern 36 may be etched away and not remain when the etching of the barrier metal layer 33 is finished.

Although not shown, an insulation layer is formed over the bit line patterns, and a storage node contact hole is formed to open a space between the bit line patterns. The space between the bit line patterns is sufficiently maintained since the bit line patterns are formed with the vertical profile. Thus, an open margin of the storage node contact hole may be maintained and a SAC margin may be increased accordingly.

In accordance with the embodiment of the present invention, the damages on the top portion of the bit line hard mask patterns may be reduced because the mask pattern is used as an etch mask when etching the metal electrode layer and the barrier metal layer. Also, the bit line patterns with a vertical profile may be formed by removing the polymers in advance using the isotropic etching process, the polymers generated when using the mask pattern until the subsequent etching processes. Consequently, a spacing distance between the bit line patterns is maintained, and thus, the SAC margin may be increased while patterning the subsequent storage node contact hole. Although this embodiment describes an application with the bit line patterns, the technological concepts of this invention may be applied in other pattern formation methods of most semiconductor devices using a hard mask layer, besides the bit line patterns. For instance, the technological concepts of this invention may be applied in a pattern formation method for etching insulation layers such as an oxide-based layer and a nitride-based layer, a pattern formation method for etching a polysilicon layer, a pattern formation method for etching a metal layer, and a method for forming a gate pattern. These pattern formation methods may also obtain a pattern in a vertical profile by removing polymers in advance.

While the present invention has been described with respect to the specific embodiments, it will be apparent to those skilled in the art that various changes and modifications may be made without departing from the spirit and scope of the invention as defined in the following claims.

What is claimed is:

1. A method for forming a pattern in a semiconductor device, comprising:
forming an etch target layer and a hard mask layer;
forming a mask pattern over the hard mask layer;
etching the hard mask layer using the mask pattern as an etch mask;
removing polymers generated while etching the hard mask layer; and
etching the etch target layer to form a pattern using the mask pattern as an etch mask.

2. The method of claim 1, wherein removing the polymers comprises performing an isotropic etching process.

3. The method of claim 2, wherein the isotropic etching process comprises performing a dry etching process using a gas having selectivity to the hard mask layer and the mask pattern to remove the polymers.

4. The method of claim 2, wherein the isotropic etching process is performed by employing an apparatus provided with a top power and a bottom power, the isotropic etching process using the top power.

5. The method of claim 4, wherein the top power ranges from approximately 100 W to approximately 2,000 W.

6. The method of claim 2, wherein the isotropic etching process is performed by employing an apparatus provided with a top power and a bottom power, the isotropic etching process using the top power and the bottom power at substantially the same time.

7. The method of claim 6, wherein the top power ranges from approximately 100 W to approximately 2,000 W and the bottom power ranges from approximately 1 W to approximately 5 W.

8. The method of claim 1, wherein the mask pattern comprises a stack structure including an amorphous carbon layer and an anti-reflective coating layer.

9. The method of claim 8, wherein the anti-reflective coating layer comprises silicon oxynitride (SiON).

10. The method of claim 8, wherein the mask pattern is formed by performing an etching process using a photoresist pattern.

11. The method of claim 1, wherein the etch target layer comprises one selected from a group consisting of a metal layer, an insulation layer, and a polysilicon layer.

12. The method of claim 1, wherein the etch target layer comprises a stack structure including a barrier metal and a metal electrode layer.

13. The method of claim 12, wherein the barrier metal comprises titanium (Ti)/titanium nitride (TiN), and the metal electrode layer comprises tungsten.

14. The method of claim 1, wherein the hard mask layer comprises a nitride-based layer, and the polymers are removed using oxygen gas.

15. The method of claim 14, wherein the oxygen gas is used at a flow rate ranging from approximately 1 sccm to approximately 30 sccm.
